(19) United States
(12) Patent Application Publication
(10) Pub. No.: US 2023/0307300 A1
(43) Pub. Date: Sep. 28, 2023

(54) PACKAGE LAYERS FOR STRESS MONITORING AND METHOD

(71) Applicant: Intel Corporation, Santa Clara, CA (US)

(72) Inventors: Jan Proschwitz, Riesa (DE); Stefan Reif, Muenchen (DE); Bernd Waidhas, Pettendorf (DE); Vishnu Prasad, Muenchen (DE)

(21) Appl. No.: 17/705,878

(22) Filed: Mar. 28, 2022

(51) Int. Cl. H01L 21/66; H01L 23/00; H01L 23/58; H01L 25/18; H01L 23/538

(52) U.S. Cl. CPC H01L 22/30; H01L 23/564; H01L 23/585; H01L 24/16; H01L 25/18; H01L 23/5385; H01L 2224/16227

(57) ABSTRACT

A semiconductor package comprises a package substrate comprised of comprised of layers of a first material. The semiconductor package includes an integrated circuit (IC) attached to the substrate at a first surface of the IC through a plurality of vias. The semiconductor package includes at least one interface layer comprised of an interface material different from the first material and sealed from exposure to air. The interface material can comprise a moisture-sensitive nonconductive material and can be disposed within the package substrate or between the first surface of the IC and the package substrate, among other locations. Other systems, apparatuses and methods are described.

### TECHNICAL FIELD

Embodiments pertain to packaging of integrated circuits (ICs). Some embodiments relate to package layers that can be used for detection of stress.

### BACKGROUND

Electronic systems often include integrated circuits (ICs) that are attached to substrate materials and packaged as a subassembly. These subassemblies are included in end products and often remain in place for years, if not decades. During that time, the subassemblies may be subjected to harsh environments and exposed to high levels of heat, humidity, mechanical forces, and other stresses. Failure of the subassemblies can cause reliability issues in the end product, leading to costly repairs, safety concerns, and other issues. Thus, there are general needs for detection of degrading subassemblies before complete failure of these subassemblies.

### BRIEF DESCRIPTION OF THE DRAWINGS

FIG. 1 is an illustration of a semiconductor package having layers comprised of an interface material in accordance with some embodiments;

FIG. 2 is an illustration of an example system for monitoring an electronic device having layers comprised of an interface material in accordance with some embodiments;

FIG. 3 is an illustration of example defects in an electronic device having layers comprised of an interface material in accordance with some embodiments;

FIG. 4 illustrates a method for monitoring a semiconductor package in accordance with some embodiments; and

FIG. 5 illustrates a system level diagram in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Electronic systems often include integrated circuits (ICs) that are attached to substrate materials and packaged as a semiconductor package. Once the semiconductor package is included in an end product, the semiconductor package is often expected to remain in place for several years and operate without failure in harsh environments such as automotive or avionics environments. If the semiconductor package fails, serious safety concerns can result.

Aspects of the disclosure address these and other concerns by providing a system comprised of, e.g., a layer of interface material (described in more detail later herein), in one or more portions of the semiconductor package. The interface material should have a different structure compared to other dielectric materials used in the semiconductor package. For example, the interface material can comprise a polymer, mold material, epoxy or other thermoset matrix.

The portion/s where this system is placed can be selected on commonly-observed failure modes of the semiconductor package, areas of previously-observed stress, etc. The systems can be sealed from the environment around the semiconductor package and can change electromagnetic behavior when the system is exposed to humidity, heat, air, or any other chemical environment. After exposure through a fault in the system, the material will change its electromagnetic behavior (RLC) over frequency and will be detectable with an on- or off-chip impedance RLC measurement. Information regarding faults, expected RLC values in non-failure mode, frequency responses of the material, and other values can be stored in a memory and the component or system identified can be replaced before hard failure.

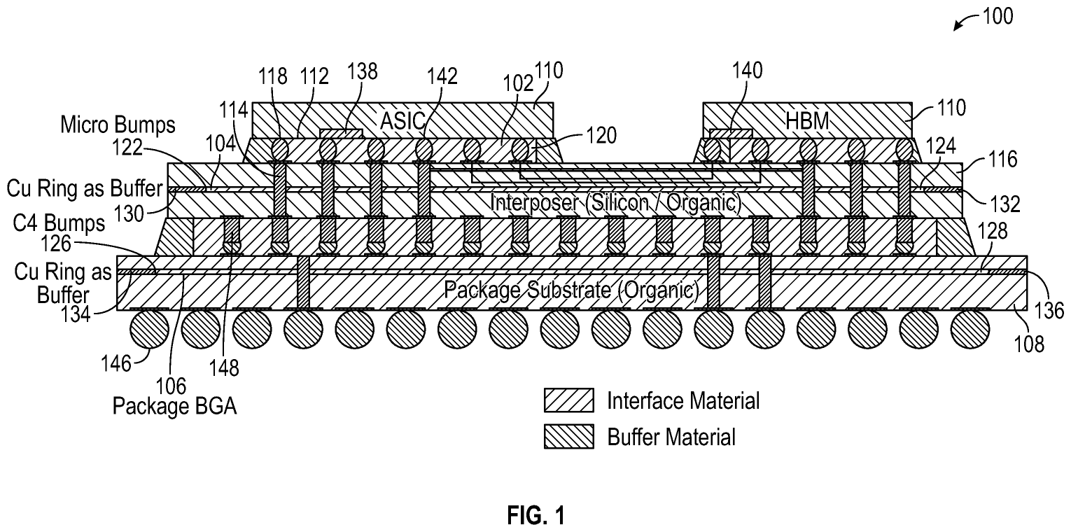

FIG. 1 is an illustration of a semiconductor package 100 having layers 102, 104, 106 comprised of an interface material in accordance with some embodiments. The semiconductor package 100 can comprise a package substrate 108 comprised of a plurality of layers of a first material. While the semiconductor package 100 is illustrated as not including a core layer, the semiconductor package 100 can include a core layer within the package substrate 108, and a plurality of build up layers comprised of conductive material sandwiched between layers of dielectric material, at least one of which can include interface material. The interface material can comprise a material that changes in impedance according to changes in temperature, humidity, or based on a chemical reaction or interaction, or a physical reaction or interaction with gases or liquids outside the semiconductor package 100, for example in the case of a liquid-based sensor.

The semiconductor package 100 can include at least one integrated circuit (IC) 110 attached to the substrate 108 at a first surface 112 of the IC 110 through a plurality of vias 114. The IC 110 can include an application-specific IC (ASIC), memory chip (e.g., high bandwidth memory (HBM) chip, etc. While two ICs 110 are shown, fewer or more than two ICs can be included in the semiconductor package 100.

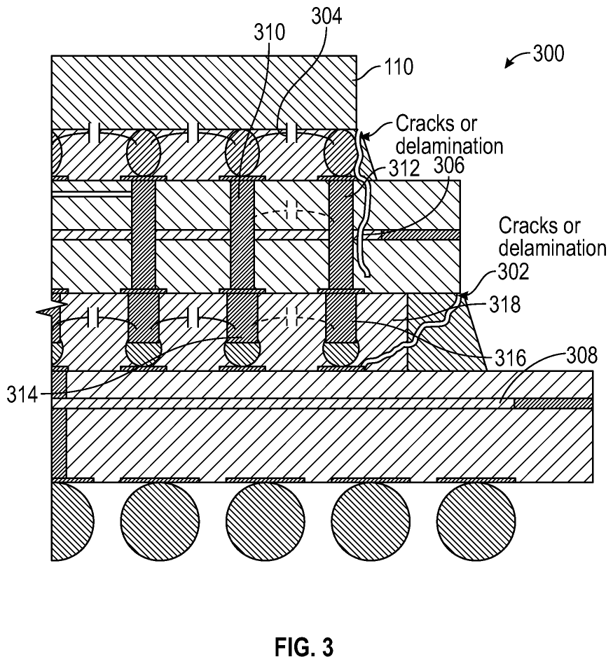

The semiconductor package 100 can include at least one interface layer 102, 104, 106 comprised of an interface material different from the first material. In general, the interface material can comprise a nonconductive material, e.g., a dielectric. The interface layer 102, 104, 106 can be disposed at one of a layer within the package substrate 108, and/or between the first surface 112 of the IC 110 and the package substrate 108, or at other areas prone to stress and cracks (see FIG. 3), or in an interposer layer 116. In embodiments, the interposer layer 116 can comprise silicon.

The interface layer 102, 104, 106 can include a first end and a second end. For example, the interface layer 102 can include a first end 118 and a second end 120. The interface layer 104 can include a first end 122 and a second end 124. The interface layer 106 can include a first end 126 and a second end 128. A buffer material can be disposed at the first end 118, 122, 126 and the second end 120, 124, 128. The buffer material being configured to seal the respective interface layer 102, 104, 106 from an environment surrounding the semiconductor package 100. In some examples, the buffer material comprises a copper ring. For example, the interface layer 104 can include a copper ring 130 at the first end 122 and a copper ring 132 at the second end 124. The interface layer 106 can include a copper ring 134 at the first end 126 and a copper ring 136 at the second end 128.

At least one IC 110 can include at least one impedance measuring circuit to measure impedance of one or more of the interface layer/s 102, 104, 106. In examples, the impedance measuring circuit/s 138, 140 can be designed and placed at design time of the IC 110 and in some examples several impedance measuring circuits can be implemented. In some examples, impedance can be measured at a plurality of points corresponding to, for example, the conductive bumps 142 on the first surface of the IC. Impedance is calculated by dividing the voltage in such a circuit by the current and will typically vary such that a fingerprint for a given interface layer 102, 104, 106 can be stored for later comparison throughout the lifetime of the semiconductor package 100, for early detection of possible semiconductor package 100 failures.

The semiconductor package 100 can include includes through layer vias (TLVs) (e.g., through ceramic vias, or TCVs). In some examples, the TLVs include plated through holes (PTHs) 114, 148. The PTHs may have having a sidewall plating that includes metal (e.g., one or more of titanium and copper).

In some examples, impedance can be measured at a plurality of points corresponding to, for example, the conductive bumps 142 on the first surface of the IC. The conductive bumps can include bonding pads, solder bumps, etc. In some embodiments the conductive bumps can correspond to bumps of a chip connector, e.g., a controlled collapse chip connector, although embodiments are not limited to any particular type of chip connector. Solder balls 144, can be, for example, ball grid arrays (BGA) made of conductive solder in an appropriate pattern to create electrical connections. Solder ball 146 can be on a second side 120 opposite the SoC device 110, for connecting semiconductor package 100 to a circuit board or other component (not shown). Other bumps can comprise chip connection bumps, for example controlled collapse chip connection (C4) bumps.

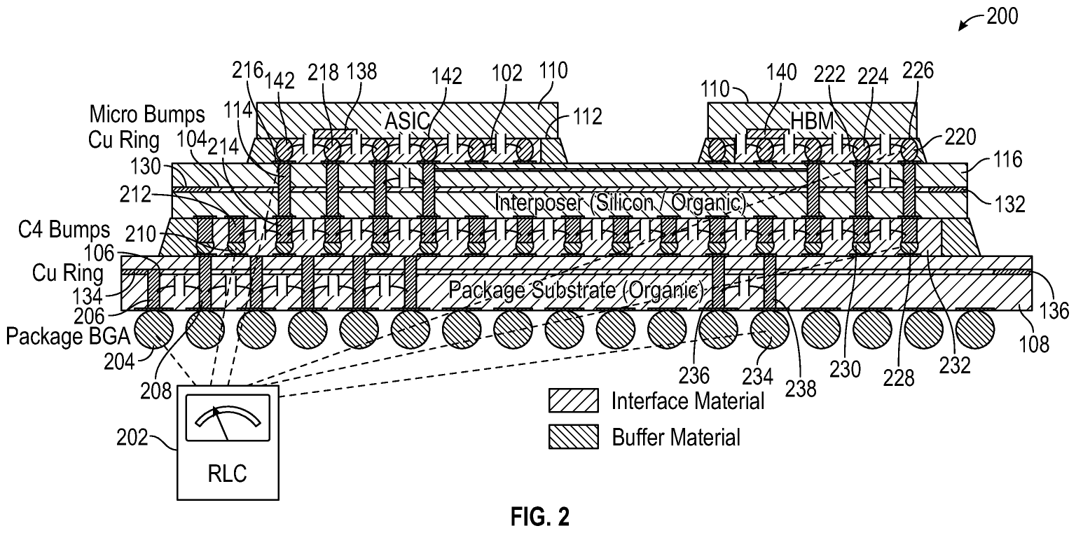

FIG. 2 is an illustration of an example system 200 for monitoring an electronic device having layers comprised of an interface material in accordance with some embodiments. Similar structures in FIG. 2 are number similarly as corresponding structures at FIG. 1. In addition to the impedance measuring circuits 138, 140, an external device 202 can measure impedance at other points. For example, the external device 202 can take voltage and current measurements 204 to measure impedance of the interface material 106 between vias 206 and 208. The external device 202 can comprise or make use of a gas or liquid chemical-based sensor. The external device 202 can take voltage and current measurements 210 to measure impedance of the interface material 106 between vias 212 and 214. The external device 202 can take voltage and current measurements 216 to measure impedance of the interface material 102 between contacts 142 and 218. The external device 202 can take voltage and current measurements 220 to measure impedance of the interface material 222 between contacts 224 and 226. The external device 202 can take voltage and current measurements 228 to measure impedance of the interface material between contacts 228 and 230. The external device 202 can take voltage and current measurements 234 to measure impedance of the interface material 106 between contacts 236 and 238.

FIG. 3 is an illustration of example defects 300, 302 in an electronic device having layers 304, 306, 308 comprised of an interface material in accordance with some embodiments. Defects can include cracks, delamination (wherein portions of a layer are removed by, for example, acid, gas, cracking, erosion, etc.) or other defects that can cause a discontinuity or change in impedance at least at some frequencies in a layer 304, 306, 308. Crack 300 can, for example, cause a change in impedance between vias 310, 312 that can be measured by detecting a change of impedance in layer 306. Crack 302 can, for example, cause a change in impedance between vias 314, 316 that can be measured by detecting a change of impedance in layer 318.

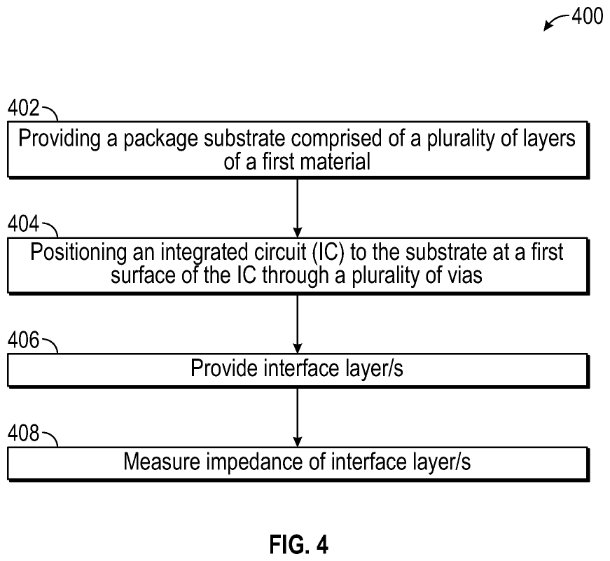

FIG. 4 illustrates a method 400 for monitoring a semiconductor package 100 in accordance with some embodiments. Reference is made to aspects of FIG. 1 and FIG. 2 and similar reference numerals as given with respect to FIG. 1 and FIG. 2 are given in the description of method 400 where appropriate.

The method 400 can begin with operation 402 with providing a package substrate 108 comprised of a plurality of layers of a first material. The method 400 can continue with operation 404 with positioning an IC 110 to the substrate at a first surface 112 of the IC through a plurality of vias 114.

The method 400 can continue with operation 406 with providing at least one interface layer 102, 104, 106 comprised of an interface material different from the first material. The interface material can be comprised of a nonconductive material, a moisture-sensitive material, etc. The interface layer/s 102, 104, 106 is/are disposed at one of a layer within the package substrate 108 or between the first surface 112 of the IC 110 and the package substrate 108.

The method 400 can continue with operation 410 with measuring impedance of the layer/s 102, 104, 106. As described above, impedance fingerprints can be taken at manufacturing time of the semiconductor package 100 to provide, e.g., baseline impedance profiles, and baseline criteria for determining when an incursion or defect has occurred in the layer/s 102, 104, 106. Measurements can be taken subsequently for comparison purposes, to provide early detection of cracking or other failures of the interface layer/s 102, 104, 106. By strategically positioning measurement circuits and interface layer/s 102, 104, 106, detection of failure can be made at points that historically have been shown to produce a greater number of cracks or other failures. Upon error detection, failures can be provided to other vehicle controllers, dashboard displays, etc., indicating failure or error conditions within the semiconductor package 100.

The methods, devices, and systems described herein provide interconnect that can accommodate high frequency signals while providing very dense signal routing. An example of an electronic device using assemblies with system level packaging as described in the present disclosure is included to show an example of a higher level device application.

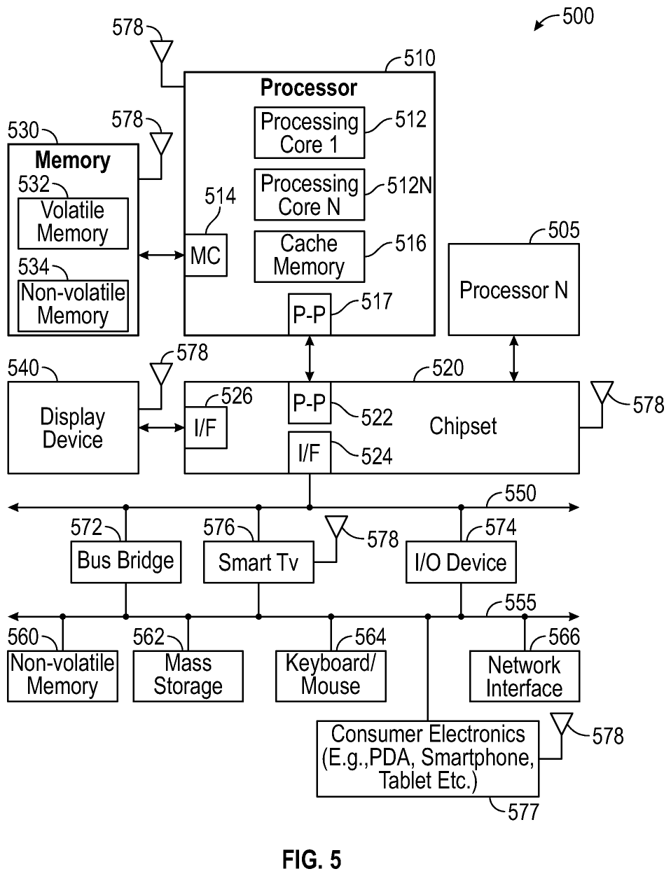

FIG. 5 illustrates a system level diagram, according to one embodiment of the invention. For instance, FIG. 5 depicts an example of a system that can include an electronic device packaged layers of interface material that can vary in impedance as failures (e.g., cracks, liquid incursions, etc.) are detected in the interface material. with a substrate including at least one layer of dielectric material comprised of at least a portion of diamond dust material. In one embodiment, system 500 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance, or any other type of computing device. In some embodiments, system 500 is a system on a chip (SOC) system. In some embodiments, some components can be included in vehicular systems (e.g., automotive, avionics, etc.). The device can include one or more semiconductor dies, which can include microprocessors, SoCs, etc.

In one embodiment, processor 510 has one or more processing cores 512 and 512N, where N is a positive integer and 512N represents the Nth processor core inside processor 510. In one embodiment, system 500 includes multiple processors including 510 and 505, where processor 505 has logic similar or identical to the logic of processor 510. In some embodiments, processing core 512 includes, but is not limited to, pre-fetch logic to fetch instructions, decode logic to decode the instructions, execution logic to execute instructions and the like. In some embodiments, processor 510 has a cache memory 516 to cache instructions and/or data for system 500. Cache memory 516 may be organized into a hierarchal structure including one or more levels of cache memory.

In some embodiments, processor 510 includes a memory controller 514, which is operable to perform functions that enable the processor 510 to access and communicate with memory 530 that includes a volatile memory 532 and/or a non-volatile memory 534. In some embodiments, processor 510 is coupled with memory 530 and chipset 520. Processor 510 may also be coupled to a wireless antenna 578 to communicate with any device configured to transmit and/or receive wireless signals. In one embodiment, the wireless antenna interface 578 operates in accordance with, but is not limited to, the IEEE 802.11 standard and its related family, Home Plug AV (HPAV), Ultra-Wide Band (UWB), Bluetooth, WiMax, or any form of wireless communication protocol.

In some embodiments, volatile memory 532 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 534 includes, but is not limited to, flash memory, phase change memory (PCM), read-only memory (ROM), electrically erasable programmable read-only memory (EEPROM), or any other type of non-volatile memory device.

Memory 530 stores information and instructions to be executed by processor 510. In one embodiment, memory 530 may also store temporary variables or other intermediate information while processor 510 is executing instructions. In the illustrated embodiment, chipset 520 connects with processor 510 via Point-to-Point (PtP or P-P) interfaces 517 and 522. Chipset 520 enables processor 510 to connect to other elements in system 500. In some embodiments of the invention, interfaces 517 and 522 operate in accordance with a PtP communication protocol such as the Intel® QuickPath Interconnect (QPI) or the like. In other embodiments, a different interconnect may be used.

In some embodiments, chipset 520 is operable to communicate with processor 510, 505N, display device 540, and other devices 572, 576, 574, 560, 562, 564, 566, 577, etc. Buses 550 and 555 may be interconnected together via a bus bridge 572. Chipset 520 connects to one or more buses 550 and 555 that interconnect various elements 574, 560, 562, 564, and 566. Chipset 520 may also be coupled to a wireless antenna 578 to communicate with any device configured to transmit and/or receive wireless signals. Chipset 520 connects to display device 540 via interface (I/F) 526. Display 540 may be, for example, a touchscreen, a liquid crystal display (LCD), a plasma display, cathode ray tube (CRT) display, or any other form of visual display device. In some embodiments of the invention, processor 410 and chipset 520 are merged into a single SOC. In one embodiment, chipset 520 couples with (e.g., via interface 524) a non-volatile memory 560, a mass storage medium 562, a keyboard/mouse 564, and a network interface 566 via I/F 524 and/or I/F 526, I/O devices 574, smart TV 576, consumer electronics 577 (e.g., PDA, Smart Phone, Tablet, etc.).

In one embodiment, mass storage medium 562 includes, but is not limited to, a solid state drive, a hard disk drive, a universal serial bus flash memory drive, or any other form of computer data storage medium. In one embodiment, network interface 566 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra-Wide Band (UWB), Bluetooth, WiMax, or any form of wireless communication protocol.

While the modules shown in FIG. 4 are depicted as separate blocks within the system 500, the functions performed by some of these blocks may be integrated within a single semiconductor circuit or may be implemented using two or more separate integrated circuits. For example, although cache memory 516 is depicted as a separate block within processor 510, cache memory 516 (or selected aspects of 516) can be incorporated into processor core 512.

The devices, systems, and methods described can provide improved thermal conductivity in electronic device packages. Examples described herein include one SoC for simplicity, but one skilled in the art would recognize upon reading this description that the examples can include more than one SoC system.

### Additional Description and Examples

Example 1 is a semiconductor package comprising a package substrate comprised of a plurality of layers of a first material; an integrated circuit (IC) attached to the substrate at a first surface of the IC through a plurality of vias; and at least one interface layer comprised of an interface material different from materials of the plurality of layers of the first material and sealed from exposure to air, the interface material comprising a moisture-sensitive nonconductive material, the interface layer disposed at one of a layer within the package substrate or between the first surface of the IC and the package substrate.

In Example 2, the subject matter of Example 1 can optionally include wherein the interface layer includes a first end and a second end, and wherein a buffer material is disposed at the first end and the second end, the buffer material being configured to seal the interface layer from an environment surrounding the semiconductor package.

In Example 3, the subject matter of Example 2 can optionally include wherein the buffer material comprises a conductive ring.

In Example 4, the subject matter of any one of Examples 1-3 can optionally include wherein the IC includes an impedance measuring circuit to measure impedance of the interface layer.

In Example 5, the subject matter of Example 4 can optionally include wherein the IC is configured to measure impedance at a plurality of points on the interface layer.

In Example 6, the subject matter of Example 5 can optionally include wherein the plurality of points corresponds to conductive bumps on the first surface of the IC.

In Example 7, the subject matter of any one of Examples 5-6 can optionally include wherein the plurality of points corresponds to bumps of a chip connector.

In Example 8, the subject matter of any one of Examples 1-7 can optionally include an interposer layer between the IC and the package substrate.

In Example 9, the subject matter of Example 8 can optionally include wherein the interposer layer comprises silicon, and wherein the interposer layer includes a layer comprised of the interface material.

In Example 10, the subject matter of Example 8 can optionally include a layer comprised of the interface material disposed between the interposer layer and the IC.

In Example 11, the subject matter of any one of Examples 1-10 can optionally include wherein the interface material comprises a material that changes in impedance according to changes in temperature.

In Example 12, the subject matter of any one of Examples 1-11 can optionally include wherein the interface material comprises a material that changes in impedance according to changes in humidity.

In Example 13, the subject matter of any one of Examples 1-12 can optionally include wherein the interface material comprises a material that changes in impedance according to a chemical interaction of the interface material with at least one of a gas or a liquid.

Example 14 is an electronic device comprising a semiconductor die coupled to a package substrate through a plurality of vias, the package substrate comprised of a plurality of layers of a first material; and at least one interface layer comprised of an interface material different from the plurality of layers of the first material and sealed from exposure to air, the interface material comprising a moisture-sensitive nonconductive material, the at least one interface layer disposed at least at one of a layer within the package substrate or between a first surface of an integrated circuit and the package substrate.

In Example 15, the subject matter of Example 14 can optionally include wherein the semiconductor die comprises a microprocessor.

In Example 16, the subject matter of any one of Examples 14-15 can optionally include wherein the semiconductor die comprises a system-on-chip (SOC).

In Example 17, the subject matter of any one of Examples 14-16 can optionally include wherein the at least one interface layer includes a first end and a second end, and wherein a buffer material is disposed at the first end and the second end, the buffer material being configured to seal the at least one interface layer from an environment surrounding the semiconductor die.

Example 18 is a method for monitoring a semiconductor package, the method comprising: providing a package substrate comprised of a plurality of layers of a first material; positioning an integrated circuit (IC) to the package substrate at a first surface of the IC through a plurality of vias; providing at least one interface layer comprised of an interface material different from the first material, the interface material comprising a nonconductive material, the at least one interface layer disposed at one of a layer within the package substrate or between the first surface of the IC and the package substrate; and measuring impedance of the at least one interface layer to determine a status of the at least one interface layer.

In Example 19, the subject matter of Example 19 can optionally include determining baseline criteria for the at least one interface layer specific to an automotive application; and storing the baseline criteria in a memory coupled to the semiconductor package.

In Example 20, the subject matter of any one of Examples 18-19 can optionally include determining baseline criteria for the at least one interface layer specific to an avionics application; and storing the baseline criteria in a memory coupled to the semiconductor package.

In Example 21, the subject matter of any one of Examples 18-20 can optionally include generating an error signal responsive to detecting that impedance of the at least one interface layer is outside a threshold.

These non-limiting examples can be combined in any permutation or combination. The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. A semiconductor package, comprising:
a package substrate comprised of a plurality of layers of a first material;
an integrated circuit (IC) attached to the package substrate at a first surface of the IC through a plurality of vias; and
at least one interface layer comprised of an interface material different from materials of the plurality of layers of the first material and sealed from exposure to air, the interface material comprising a moisture-sensitive nonconductive material, the at least one interface layer disposed at one of a layer within the package substrate or between the first surface of the IC and the package substrate.

2. The semiconductor package of claim 1, wherein the at least one interface layer includes a first end and a second end, and wherein a buffer material is disposed at the first end and the second end, the buffer material being configured to seal the at least one interface layer from an environment surrounding the semiconductor package.

3. The semiconductor package of claim 2, wherein the buffer material comprises a conductive ring.

4. The semiconductor package of claim 1, wherein the IC includes an impedance measuring circuit to measure impedance of the at least one interface layer.

5. The semiconductor package of claim 4, wherein the IC is configured to measure impedance at a plurality of points on the at least one interface layer.

6. The semiconductor package of claim 5, wherein the plurality of points corresponds to conductive bumps on the first surface of the IC.

7. The semiconductor package of claim 5, wherein the plurality of points corresponds to bumps of a chip connector.

8. The semiconductor package of claim 1, further comprising an interposer layer between the IC and the package substrate.

9. The semiconductor package of claim 8, wherein the interposer layer comprises silicon, and wherein the interposer layer includes a layer comprised of the interface material.

10. The semiconductor package of claim 8, further comprising a layer comprised of the interface material disposed between the interposer layer and the IC.

11. The semiconductor package of claim 1, wherein the interface material comprises a material that changes in impedance according to changes in temperature.

12. The semiconductor package of claim 1, wherein the interface material comprises a material that changes in impedance according to changes in humidity.

13. The semiconductor package of claim 1, wherein the interface material comprises a material that changes in impedance according to a chemical interaction of the interface material with at least one of a gas or a liquid.

14. An electronic device comprising:
a semiconductor die coupled to a package substrate through a plurality of vias, the package substrate comprised of a plurality of layers of a first material; and
at least one interface layer comprised of an interface material different from the plurality of layers of the first material and sealed from exposure to air, the interface material comprising a moisture-sensitive nonconductive material, the at least one interface layer disposed at least at one of a layer within the package substrate or between a first surface of an integrated circuit and the package substrate.

15. The electronic device of claim 14, wherein the semiconductor die comprises a microprocessor.

16. The electronic device of claim 14, wherein the semiconductor die comprises a system-on-chip (SOC).

17. The electronic device of claim 14, wherein the at least one interface layer includes a first end and a second end, and wherein a buffer material is disposed at the first end and the second end, the buffer material being configured to seal the at least one interface layer from an environment surrounding the semiconductor die.

18. A method for monitoring a semiconductor package, the method comprising:
providing a package substrate comprised of a plurality of layers of a first material;
positioning an integrated circuit (IC) to the package substrate at a first surface of the IC through a plurality of vias;
providing at least one interface layer comprised of an interface material different from the first material, the interface material comprising a nonconductive material, the at least one interface layer disposed at one of a layer within the package substrate or between the first surface of the IC and the package substrate; and
measuring impedance of the at least one interface layer to determine a status of the at least one interface layer.

19. The method of claim 18, further comprising:
determining baseline criteria for the at least one interface layer specific to an automotive application; and
storing the baseline criteria in a memory coupled to the semiconductor package.

20. The method of claim 18, further comprising:
determining baseline criteria for the at least one interface layer specific to an avionics application; and
storing the baseline criteria in a memory coupled to the semiconductor package.

21. The method of claim 18, further comprising:
generating an error signal responsive to detecting that impedance of the at least one interface layer is outside a threshold.
